(19) United States
(12) Patent Application Publication
(10) Pub. No.: US 2018/0145199 A1
(43) Pub. Date: May 24, 2018

(54) SOLAR MODULE WITH CENTRAL INTERCONNECTION

(71) Applicant: HANWHA Q CELLS GMBH, Bitterfeld-Wolfen OT Thalheim (DE)

(72) Inventors: Markus TRÄGER, Leipzig (DE); Michael METTE, Bitterfeld (DE); Andreas PFENNIG, Leipzig (DE); Hans-Jürgen BÄCKER, Hamburg (DE)

(73) Assignee: HANWHA Q CELLS GMBH, Bitterfeld-Wolfen OT Thalheim (DE)

(21) Appl. No.: 15/575,142

(22) PCT Filed: May 18, 2016
(86) PCT No.: PCT/DE2016/100229

§ 371 Date: Nov. 17, 2017

(30) Foreign Application Priority Data
May 19, 2015 (DE) 10 2015 107 878.3

(51) Int. Cl. H01L 31/05

(52) U.S. Cl. CPC H01L 31/0504; H01L 31/0512

(57) ABSTRACT

The present invention relates to a solar module (1) comprising at least two solar cells (3, 5), wherein each of the solar cells (3, 5) comprises an upper end (21), a lower end (23) which is situated opposite the upper end (21), two opposite side ends (25, 27) and at least one busbar (11, 13) which extends from the first side end (25) to the opposite second side end (27) of the solar cell (3, 5), wherein at least one finger (7, 9) of the solar cell (3, 5) makes electrical contact with the busbar (11, 13), wherein at least one first busbar (11) of at least one first solar cell (3) is arranged at a first side end (25), which is situated opposite a second side end (27) of at least one second solar cell (5) which is arranged or can be arranged next to the first solar cell, at a first distance from the upper end (21) of the at least one first solar cell (3), and at least one second busbar (13) of the at least one second solar cell (5) is arranged at the second side end (27) at a second distance from the upper end (21) of the at least one second solar cell (5), wherein the first distance is not identical to the second distance, and therefore the busbars (11, 13) of the solar cells (3, 5) are arranged offset in relation to one another at the side ends (25, 27) of the solar cells (3, 5).

The present invention relates to a solar module comprising at least two solar cells, wherein each of the solar cells comprises an upper end, a lower end which is situated opposite the upper end, two opposite side ends, and at least one busbar which extends from the first side end to the opposite second side end of the solar cell, wherein at least one finger of the solar cell makes electrical contact with the busbar.

In response to light exposure, individual solar cells deliver only small currents and voltages. Consequently, these are customarily interconnected to form a solar module, which is capable of delivering the desired voltages and currents. To this end for example a plurality of solar cells are connected in series, wherein cell connectors are employed, which constitute an electrical connection between the solar cells. In solar modules, for the parallel connection of series-connected solar cell strings, cross-connectors are additionally employed, wherein cross-connectors for parallel connection are customarily arranged at the ends of the solar cell strings.

As cell connectors and cross-connectors, inter alia, metal strips, e.g. copper strips are employed, with or without an additional metal or alloy coating. For each connection between two solar cell strings which are to be electrically connected, a metal strip of this type is provided as a separate cross-connector. The cell connectors themselves are then soldered to the cross-connector, wherein the cell connectors must be arranged with accurate positioning on the cross-connectors, in order to achieve the desired electrical interconnection. In the case of cross-connectors arranged at a string end, this can be achieved in a relatively problem-free manner, as the individual cell connectors on solar cells strings configured with a mutual parallel offset are arranged with a substantial mutual clearance.

In order to increase the efficiency of solar cells, rear contact solar cells have been developed, wherein front-side shading associated with metallic conductors (busbars), and the copper strips soldered thereto, is reduced. However, these cells are also more difficult to connect in series, as the contacts for both polarities must be formed adjacently on the rear side. It is therefore difficult to route the metal connecting elements from one cell to another, without forming a short-circuit to surfaces of the other respective polarity.

For the solution of this problem, e.g. by means of “strip technology”, the conventional stringer technique using copper strips has been employed. In this case, the contact pattern must be applied asymmetrically to the reverse side of the solar cells, in order to permit the linear routing of strips from cell to cell, such that the emitter contacts of one cell can be connected to the base contacts of the next cell.

Notwithstanding the asymmetrical arrangement of the copper strips, the general cell design has not been adapted with respect to the mutual relative arrangement of busbars of two solar cells, in order to improve the interconnection of solar cells. Strip technology only involves the formation of contacts on the respective cell, wherein the cell design of the solar cells is not dependent upon the cell design of further solar cells.

In the alternative thin-film technology, a reverse side teflar foil is coated with copper foil, in which connecting paths are formed by etching, and are then coated with a solder stop mask.

However, the high efficiency of modern solar cells also has a disadvantage, in that the high cell current is routed from one cell, to the next via a resistor, thereby resulting in a high ohmic power loss.

The halving of solar cells transversely to the direction of current conduction is therefore known, together with the series connection of the resulting half-cells, such that the voltage is doubled and the current strength is halved. This results in a one-quarter reduction in the power loss. A cell design of this type is described as a half-cut cell.

It has also proved to be advantageous, not only that the solar cells themselves are configured in the form of half-cut cells but, alternatively or additionally, a series-connected string of solar cells is configured with a central parallel connection, by means of cross-connectors (central interconnection).

The central interconnection of solar cells is problematic, in that the metal strips constituting the electrical conductors must be accurately applied to the cross-connectors. As already described above, to date, the parallel connection of solar cell strings has invariably been completed at the string end, such that the cell connectors of the parallel-connected solar cells are arranged with a substantial mutual clearance. For central interconnection, this is not the case. In central interconnection of this type, when the fingers of the busbars which connect the solar cells are in exact opposition, the solder strips will also be in exact opposition At present, a reliable automatic deposition of solder strips on a cross-connector is not possible.

The object of the present invention is therefore the disclosure of a device which overcomes the disadvantages of the prior art. Specifically, a device is disclosed which permits the central interconnection of solar modules with a high degree of reliability and low costs, in an automated process.

This object is fulfilled, wherein at least one first busbar of at least one first solar cell is arranged at a first side end, which is situated opposite a second side end of at least one second solar cell which is arranged or can be arranged next to the first solar cell, at a first distance from the upper end of the at least one first solar cell, and at least one second busbar of the at least one second solar cell is arranged at the second side end at a second distance from the upper end of the at least one second solar cell, wherein the first distance is not identical to the second distance, such that the end points of the busbars of the solar cells are arranged offset in relation to one another at the side ends of the solar cells.

According to the invention, the end points of the busbars of the solar cells are thus configured with a mutually offset arrangement in relation to the side ends of the solar cell. The electrical conductors which are bonded to the busbars are thus not in opposition, but are mutually offset, such that each can be accurately positioned in relation to a cross-connector in an automated process.

It is evident that the terms upper end, lower end, and first and second side end are provided solely in the interests of a better understanding of the invention. An upper end can naturally be a lower end and, in the same way, the second side end can be the first side end, and vice versa.

According to the invention, it can thus be provided that all the busbars of the at least one first solar cell are arranged at different distances from the upper end of the at least one first solar cell than all the busbars of the at least one second solar cell from the upper end of the at least one second solar cell.

Although solar cells comprising at least one busbar are known from the prior art, embodiments are also known in which the fingers of the solar cells are bonded with more than one busbar. According to the invention, it is advantageous if all the busbars of the first and second solar cell are configured in a mutually offset arrangement.

It can also be provided that the at least one first and the at least one second busbar are connectable or connected by means of an electrical connecting element, specifically by means of an electrical connecting element in the form of a solder strip.

In one exemplary embodiment according to the invention, it can also be provided that the busbars are configured in a one-piece arrangement or integrally to the electrical connecting elements or, for example, the solder strips simultaneously constitute the busbars.

In one exemplary embodiment according to the invention, it can also be advantageous that at least one or exactly one cross-connector is provided for the parallel electrical connection of the at least one first and the at least one second solar cell, wherein the cross-connector can be arranged or is arranged between the at least one first and the at least one second solar cell, wherein, specifically, the electrical connecting elements of the at least one first and the at least one second busbar are electrically connectable or connected to the cross-connector.

In this form of embodiment, an optimum reduction in manufacturing costs can be achieved. Specifically, it is possible to form a parallel circuit connection of a first and second solar cell using a single cross-connector.

It can be provided that at least one third solar cell and at least one fourth cell are included, wherein the second side end of the at least one third solar cell is arranged in opposition to the first side end of the at least one first solar cell, and wherein the first side end of the at least one fourth solar cell is arranged in opposition to the second side end of the at least one second solar cell such that, specifically, a solar cell string with central interconnection is provided or can be provided.

Central interconnection of this type advantageously provides an optimum ohmic resistance.

It can also be provided that a cross-connector connects the at least one first and the at least one second solar cell in parallel.

According to one form of embodiment of the invention, the solar cells of the solar module are arranged in a string configuration, wherein the width of each solar cell, measured from the first side end to the second side end and/or the height of each solar cell, measured from the upper end to the lower end, is identical and, moreover, the clearance between the solar cells is specifically identical.

An arrangement of this type permits an optimum electric circuit connection of solar cells of equal capacity, wherein the mutual displacement of the busbars does not, in itself, result in any optical impairment of the overall impression.

It can also be provided that the at least one first and/or the at least one second busbar is arranged parallel to the upper and/or the lower end of the at least one first and/or second solar cell, or is oriented at a first angle α to the upper and/or lower end of the at least one first and/or second solar cell.

According to the invention, the orientation of the busbars can be selected virtually at will, wherein the advantage of the invention, in that the ends of the busbars are configured in a mutually offset arrangement on the side ends of two solar cells, is not dependent upon the further orientation of the busbars.

Specifically, it can also be advantageous that the at least one first and the at least one second solar cells are configured in the form of half-cut cells. It can thus be provided that the at least one first and/or the at least one second busbar, on or in the region of the side ends of the half-cut cells, incorporate a region comprising a soldering flux, wherein electrical connecting elements for the parallel connection of the at least one first and second solar cells are arranged, or can be arranged on the region which incorporates the soldering flux, or are electrically bondable or bonded to the latter.

Specifically in half-cut cells, an inherently displaced layout of this type within a solar cell has an advantage in that, under certain circumstances, half-cut cells cannot undergo soldering/stringing at the laser-cut/perforated cell edge. Here again, this form of embodiment according to the invention permits the optimum bonding of the busbar with for example a cross-connector.

It will thus be evident to a person skilled in the art that the first solar cell, within the meaning of the present invention, is constituted by a first half of the half-cut solar cell, and the second solar cell is constituted by the second half of the half-cut cell.

The invention is based upon the surprising finding to the effect that, by an offset arrangement of the busbars “on” or “of” (as before) two solar cells, a simple, reliable and automated connection of the latter, by means of cross-connectors, can be achieved for the central interconnection of solar cells.

Further characteristics and advantages of the invention proceed from the following description, in which exemplary embodiments of the invention are described with reference to schematic drawings for exemplary purposes, without restricting the invention.

Herein:

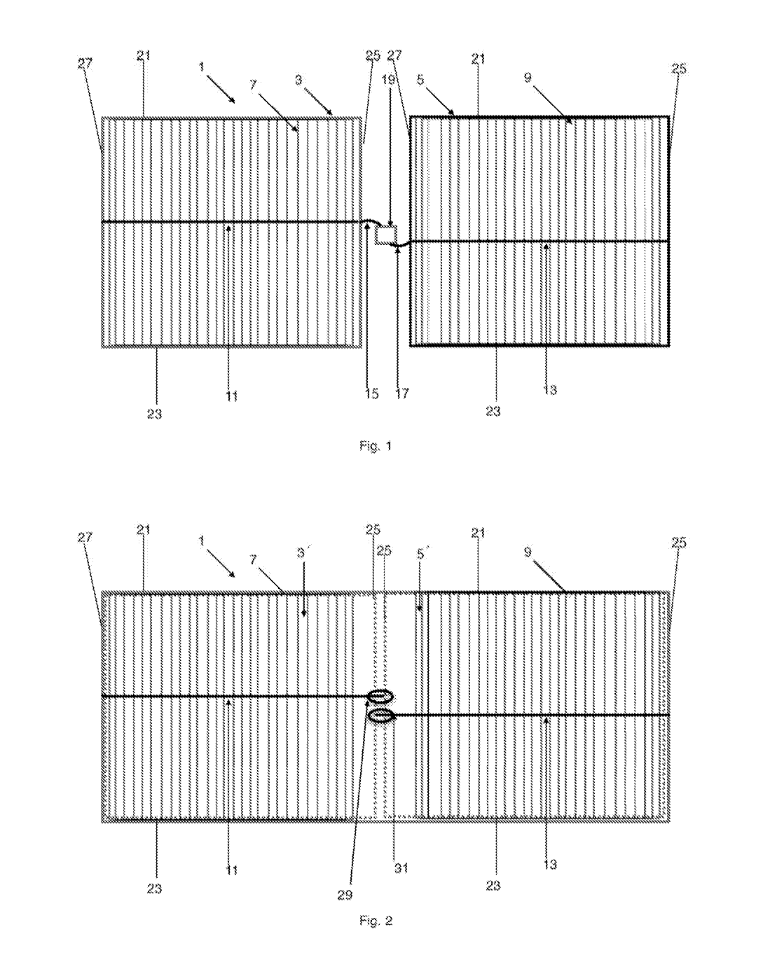

FIG. 1: shows a schematic view of a first form of embodiment of a solar module according to the invention and

FIG. 2: shows a schematic view of an alternative form of embodiment of a solar module according to the invention.

FIG. 1 shows a first form of embodiment of a solar module 1 according to the invention. The latter comprises two solar cells 3,5, wherein each of the solar cells 3,5 has an upper end 21, a lower end 23, and two opposing side ends 25, 27.

The solar cells 3,5 moreover comprise fingers 7,9, which are electrically bonded to busbars 11, 13 of the solar cells 3,5. The busbars 11, 13 extend respectively from the first side end 23 to the opposite second side end 25 of the solar cells 3,5.

The arrangement of the first busbar 11 is offset in relation to the second busbar 13, i.e. in the region of the first side end 25 of the first solar cell 3, the first busbar 11 is not positioned opposite the second busbar 13 on the second side end 27 of the second solar cell 5.

Specifically, according to the invention, it can be advantageous if the solar cells 3,5 comprise a plurality of busbars (not represented), wherein all the busbars 11 of the at least one first solar cell 3 are arranged at different distances from the upper end 21 of the first solar cell 3 than all the busbars 13 of the second solar cell 5.

For the further electrical bonding of the electrical connectors, the solar module 1 comprises electrical connecting elements 15, 17, which are bonded to the busbars 11, 13. In the form of embodiment represented, the electrical connecting elements 15, 17 are configured in the form of solder strips.

The electrical connecting elements 15, 17 are electrically bonded by means of a cross-connector 19, which connects the solar cells 3, 5 in parallel. The advantage of the present invention is thus clarified. By the reciprocal offsetting of the busbars 11, 13 and the electrical connectors 15, 17, a secure deposition of the latter upon the cross-connector 19 can be automated without difficulty, specifically if the cross-connector 19, as represented, is arranged between the solar cells 3, 5.

Specifically, it can be provided that further solar cells (not represented) are arranged to the left of the first solar cell 3 and to the right of the second solar cell 5, such that a linear solar cell string is constituted. The further solar cells are thus preferably connected in series with the first or the second solar cell 3,5, such that a series-parallel circuit arrangement of a solar cell string is achieved.

It is directly evident from FIG. 1 that the dimensions of the solar cells 3, 5 are identical, such that the width and height thereof are the same. Advantageously, this also applies to the unrepresented solar cells in the solar cell string. Accordingly, solar cells with identical electrical properties are interconnected and [ . . . ].

FIG. 2 shows an alternative form of embodiment of a solar module according to the invention. This comprises a first and a second solar cell 3′, 5′ which are configured in the form of half-cut cells. The first and the second busbar 11,13, on the side ends 25, 27 of the half-cut cells, incorporate a region 29, 31 which comprises a soldering flux. On this region 29, 31, the electrical connecting elements (not represented) are bondable for the parallel connection of the two half-cut cells 3′, 5′.

The characteristics of the invention disclosed in the above description, the claims and the drawings, whether individually or in any desired combination, may be essential to the realization of the invention in its various forms of embodiment.

1. A solar module comprising at least two solar cells, wherein each of the solar cells comprises an upper end, a lower end which is situated opposite the upper end, two opposite side ends and at least one busbar, which extends from the first side end to the opposite second side end of the solar cell, wherein at least one finger of the solar cell makes electrical contact with the busbar, wherein
at least one first busbar of at least one first solar cell is arranged at a first side end, which is situated opposite a second side end of at least one second solar cell, which is arranged or can be arranged next to the first solar cell, at a first distance from the upper end of the at least one first solar cell, and
at least one second busbar of the at least one second solar cell is arranged at the second side end at a second distance from the upper end of the at least one second solar cell, wherein the first distance is not identical to the second distance, and therefore the busbars of the solar cells are arranged offset in relation to one another at the side ends of the solar cells.

2. The solar module as claimed in claim 1, wherein all the busbars of the at least one first solar cell are arranged at different distances from the upper end of the at least one first solar cell than all the busbars of the at least one second solar cell from the upper end of the at least one second solar cell.

3. The solar module as claimed in claim 1, wherein
the at least one first and the at least one second busbar are connectable or connected by means of an electrical connecting element, specifically by means of an electrical connecting element in the form of a solder strip.

4. The solar module as claimed in claim 1, further comprising at least one or exactly one cross-connector for the parallel electrical connection of the at least one first and the at least one second solar cell, wherein the cross-connector can be arranged or is arranged between the at least one first and the at least one second solar cell, wherein, specifically, the electrical connecting elements of the at least one first and the at least one second busbar are electrically connectable or connected to the cross-connector.

5. The solar module as claimed in claim 4, wherein at least one third solar cell and at least one fourth solar cell are included, wherein the second side end of the at least one third solar cell is arranged in opposition to the first side end of the at least one first solar cell, and wherein the first side end of the at least one fourth solar cell is arranged in opposition to the second side end of the at least one second solar cells such that, specifically, a solar cell string with central interconnection is provided or can be provided.

6. The solar module as claimed in claim 4, wherein
a cross-connector connects the at least one t and the at least one second solar cell in parallel.

7. The solar module as claimed in claim 1, wherein
the solar cells of the solar module are arranged in a string configuration, wherein the width of each solar cell, measured from the first side end to the second side end and/or the height of each solar cell, measured from the upper end to the lower end, is identical and, moreover, the clearance between the solar cells is specifically identical.

8. The solar module as claimed in claim 1, wherein at least one first and/or the at least one second busbar is arranged parallel to the upper and/or the lower end of the at least one first and/or second solar cell, or is oriented at a first angle α to the upper and/or lower end of the at least one first and/or second solar cell.

9. The solar module as claimed in claim 1,
wherein at least one first and the at least one second solar cell are configured in the form of half-cut cells.

10. The solar module as claimed in claim 9, wherein at least one first and/or the at least one second busbar, on or in the region of the side ends of the half-cut cells, incorporate a region comprising a soldering flux, wherein electrical connecting elements for the parallel connection of the at least one first and second solar cells are arranged, or can be arranged on the region which incorporates the soldering flux, or are electrically bondable or bonded to the latter.
